(19) United States
(12) Patent Application Publication
(10) Pub. No.: US 2026/0354065 A1
(43) Pub. Date: Nov. 5, 2026

(54) SUBSTRATE ETCHING WITH PLASMA JET

(71) Applicant: Lam Research Corporation, Fremont, CA (US)

(72) Inventors: Shaun Tyler Smith, Portland, OR (US); Paul Konkola, West Linn, OR (US); Yukinori Sakiyama, West Linn, OR (US); Jacob Lee Hiester, Newberg, OR (US); Jason Gordon Galginaitis, Portland, OR (US); Karl Frederick Leeser, West Linn, OR (US)

(21) Appl. No.: 19/487,465

(22) PCT Filed: Jun. 7, 2024
(86) PCT No.: PCT/US2024/033135

§ 371 Date: Nov. 24, 2025

Related U.S. Application Data
(60) Provisional application No. 63/507,974, filed on Jun. 13, 2023.

(51) Int. Cl. H10P 50/24; H01J 37/32; H10P 72/00

(52) U.S. Cl. CPC H10P 50/24; H01J 37/3244; H01J 37/32568; H01J 37/32715; H10P 72/0421; H01J 2237/20214; H01J 2237/334

(57) ABSTRACT

Techniques and apparatus are provided for processing a semiconductor substrate. In some embodiments, techniques may include: receiving at least an edge portion of the semiconductor substrate at a region between a first electrode and a second electrode, the region comprising one or more ledge features each configured to prevent plasma from diffusing out of the region; receiving a process gas and an inert gas from one or more inlets; using the first and second electrodes and the process gas, generating a point plasma confined in the region between the first and second electrodes by the one or more ledge features; and etching the edge portion of the semiconductor substrate using an etchant produced on the edge portion by the point plasma while the semiconductor substrate is rotating between and relative to the first and second electrodes.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor manufacturing processes may create layers of films on a semiconductor substrate or wafer during fabrication, and may result in unwanted materials or metals on the substrate, particularly on the edge. Some processes such as edge bevel removal (EBR) can substantially process the edge of the wafer to remove the material. EBR can be performed by applying a reactive species (e.g., etchant) generated by a plasma source in a reduced-pressure environment to remove material where desired, such as at the edge of the wafer. However, conventional EBR in reduced pressure is reaching its performance limits as requirements for etch rate, yield, and precision of the etching profile are increasing.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the present disclosure, a method of processing a semiconductor substrate is disclosed. In some embodiments, the method may include: receiving at least an edge portion of the semiconductor substrate at a region between a first electrode and a second electrode, the region comprising one or more ledge features each configured to prevent plasma from diffusing out of the region; receiving a process gas and an inert gas from one or more inlets; using the first and second electrodes and the process gas, generating a point plasma confined in the region between the first and second electrodes by the one or more ledge features, the point plasma having a pressure of at least 200 Torr; and etching the edge portion of the semiconductor substrate using an etchant produced on the edge portion by the point plasma while the semiconductor substrate is rotating between and relative to the first and second electrodes.

In some embodiments, the method may include: receiving an edge portion of the semiconductor substrate at a region between a first electrode and a second electrode, the region comprising one or more confinement ledges; generating an etchant having a pressure of at least 200 Torr using a reactant gas and the first electrode; transporting, with a carrier gas, the etchant toward the edge portion of the semiconductor substrate positioned proximate the first electrode; and etching the portion of the semiconductor substrate using the etchant while the semiconductor substrate is rotating between the first and second electrodes, wherein the etchant is contained within the region by the one or more confinement ledges.

In another aspect of the present disclosure, an apparatus configured to process a semiconductor substrate is disclosed. In some embodiments, the apparatus may include: a first electrode; a second electrode disposed opposite to the first electrode to form a region sized to receive at least a portion of the semiconductor substrate between the first electrode and the second electrode, wherein the first and second electrodes are configured to couple to a power source; one or more confinement ledges proximate the region and configured to confine gas and plasma; a first gas inlet; a second gas inlet; and a controller configured to couple to the first and second electrodes and the power source, the controller further configured to: when coupled to the first and second electrodes and the power source, apply power from the power source to the first and second electrodes to cause generation of plasma in the region using the first and second electrodes based at least on a process gas received via the first gas inlet, the process gas delivered to the region with a carrier gas from the second gas inlet, the plasma at least partially confined in the region by the one or more confinement ledges and having a pressure of at least 200 Torr, and etch at least the portion of the semiconductor substrate using the generated plasma while the semiconductor substrate is rotating.

These and other features of the disclosed embodiments will be described in detail below with reference to the associated drawings.

### BRIEF DESCRIPTION OF DRAWINGS

FIGS. 1A and 1B are simplified diagrams of hardware configurations for material removal from a semiconductor substrate using a plasma source, according to some embodiments.

FIG. 2 is an overview diagram of a hardware configuration for a material removal system configured to provide a pressurized jet of plasma toward a of a semiconductor substrate, according to some embodiments.

FIG. 2A is a cross-sectional view of the overview diagram of the hardware configuration for the material removal system of FIG. 2.

FIGS. 2B and 2C are cross-sectional views of portions of the material removal system of FIG. 2, showing components of the system and a confinement ledge useful for implementing the system.

FIGS. 2D and 2E illustrate indirect and direct plasma generation that may be used with the material removal system described herein.

FIG. 2F illustrates three factors that may be involved in processing a wafer edge using a plasma source, including radical generation, transportation, and surface reaction.

FIG. 2G a closer view of hardware configuration of material removal system, according to some embodiments.

FIG. 2H is a cross-sectional views of the plasma source with a confinement ledge.

FIG. 2I is a cross-sectional views of the plasma source with multiple confinement ledges.

FIG. 3 is a flow diagram illustrating a method of processing a semiconductor substrate, according to some embodiments.

FIG. 4 is a flow diagram illustrating another method of processing a semiconductor substrate, according to some embodiments.

FIG. 5 illustrates a simplified block diagram of a system or apparatus as described herein.

### DETAILED DESCRIPTION

The following terms are used throughout the present specification:

A “semiconductor device fabrication operation” as used herein is an operation performed during fabrication of semiconductor devices. As referred to herein, such a fabrication operation is sometimes simply referred to as a “process” or as “processing.” Examples of processing include deposition of a material on a substrate, selectively etching material from a substrate, and ashing of photoresist on a substrate. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Examples of semiconductor substrate materials include silicon (Si), gallium arsenide (GaAs), and silicon germanium (SiGe).

Besides semiconductor wafers, other workpieces that may take advantage of the disclosed embodiments include various articles such as magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

This disclosure generally relates to processing a semiconductor substrate to, e.g., remove unwanted materials from a portion of the substrate such as an edge of the substrate. An enhanced approach that remains cost effective and reduces system footprint is desirable. Moreover, the currently disclosed embodiments can obviate manual re-design of the system and the lengthy time needed to optimize the hardware configuration.

Such an enhanced approach, according to some embodiments of the present disclosure, may leverage so-called atmospheric pressure plasma jet (APPJ) technology for edge bevel removal (EBR) technology in recipe-controlled etching to remove material (e.g., one or more existing layers) from portions of a semiconductor substrate, which in some aspects may involve operating one or more nozzles at atmospheric conditions to provide a pressurized jet of plasma radicals toward the substrate. Since APPJ may be used to deposit material using certain configurations, the present disclosure is not necessarily limited to etching. That is, the material removal system may be used for deposition despite its naming, and the functionalities thereof are not limited to material removal. However, the following description will primarily focus on material removal using etching for enhanced EBR.

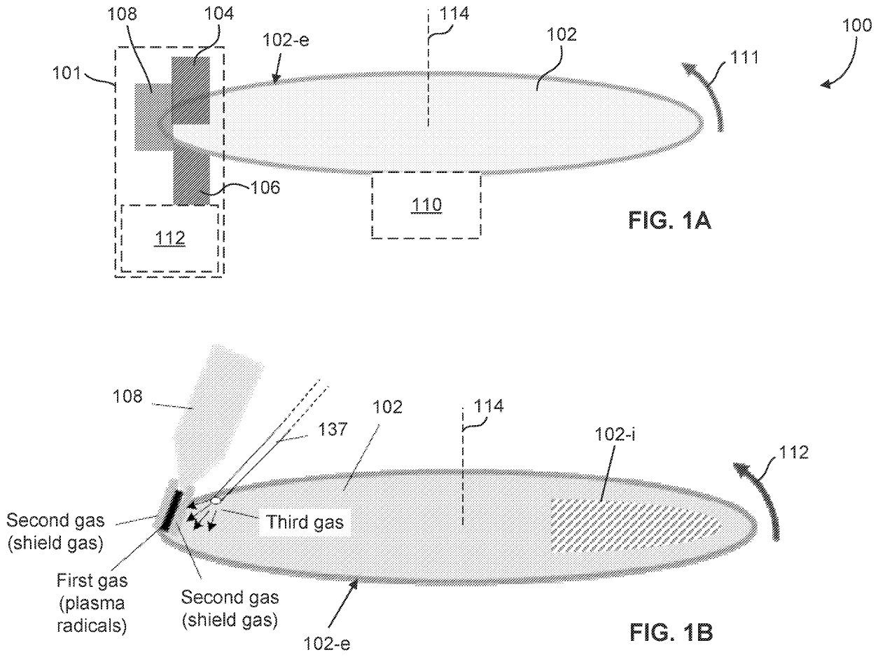

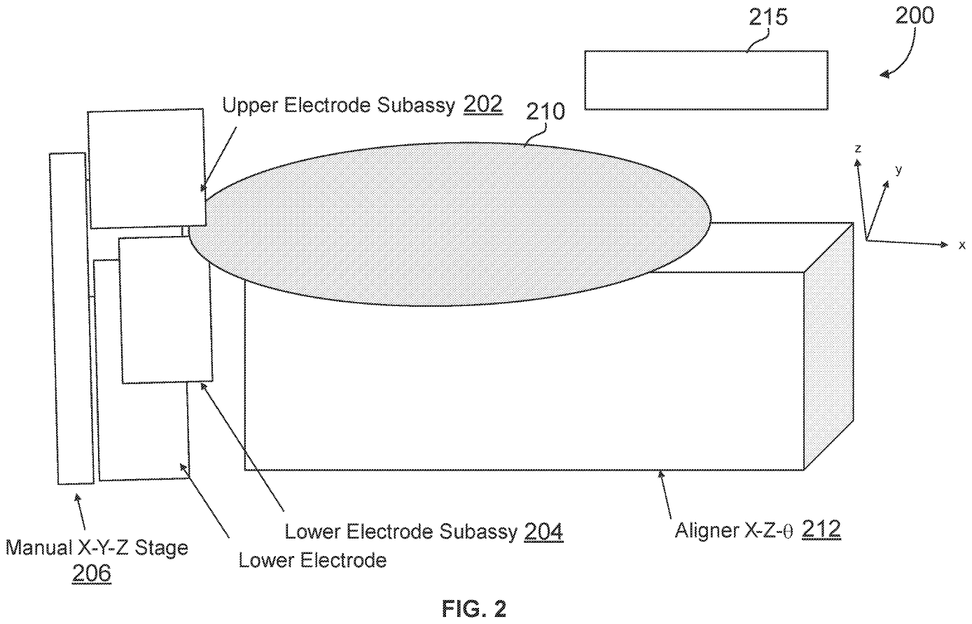

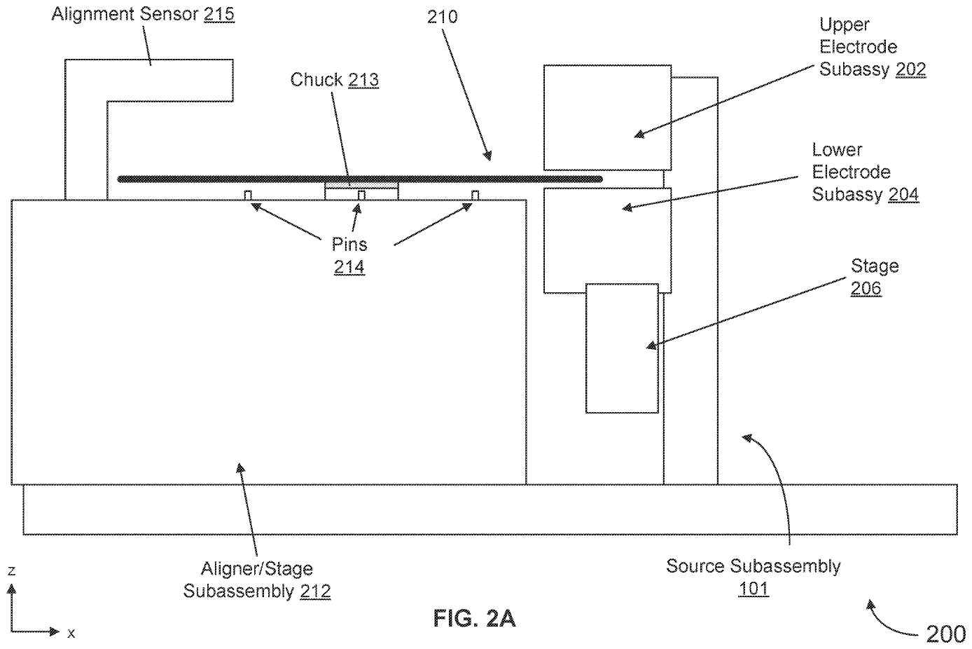

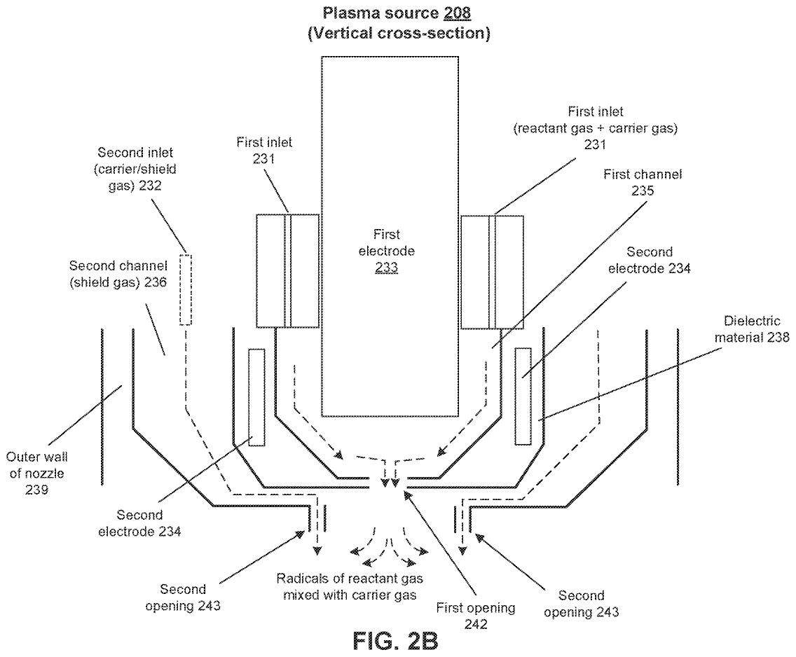

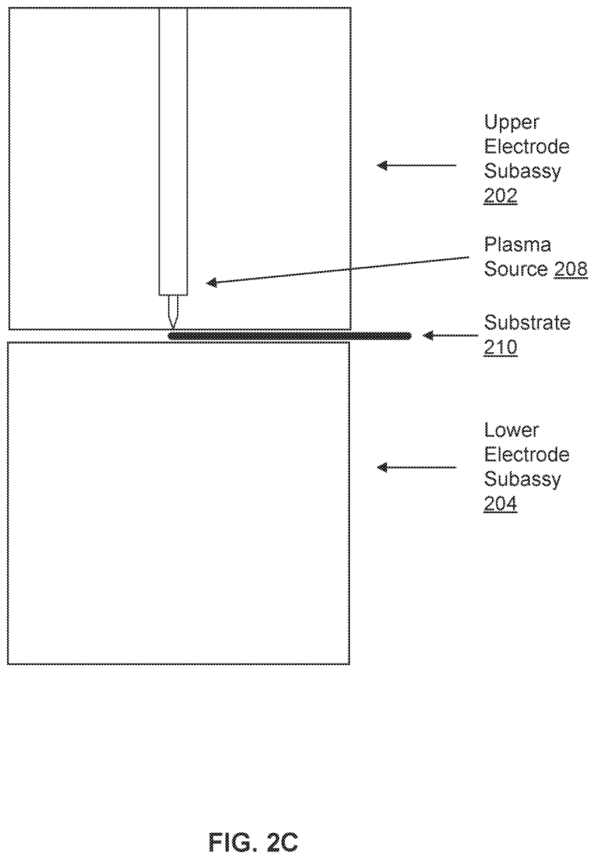

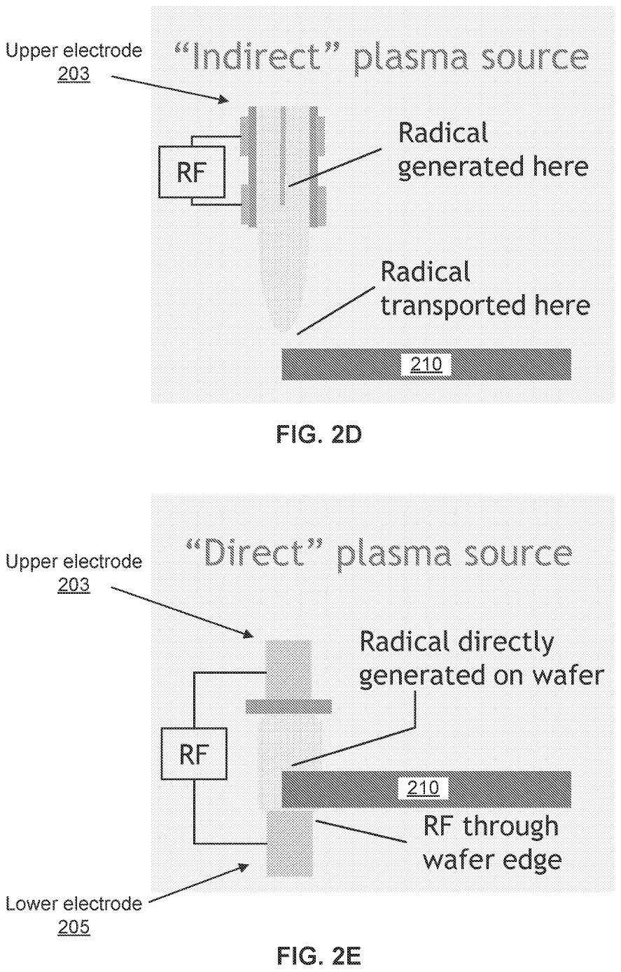

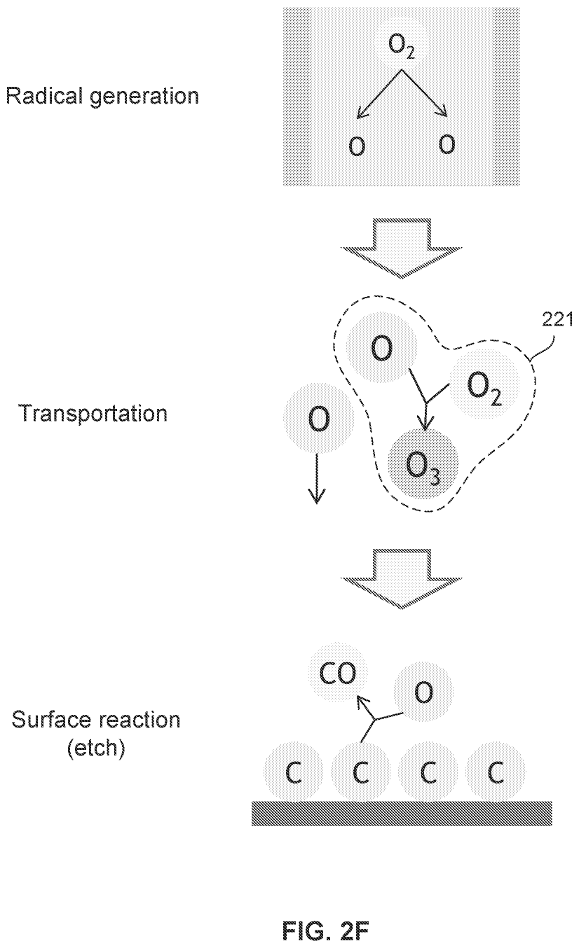

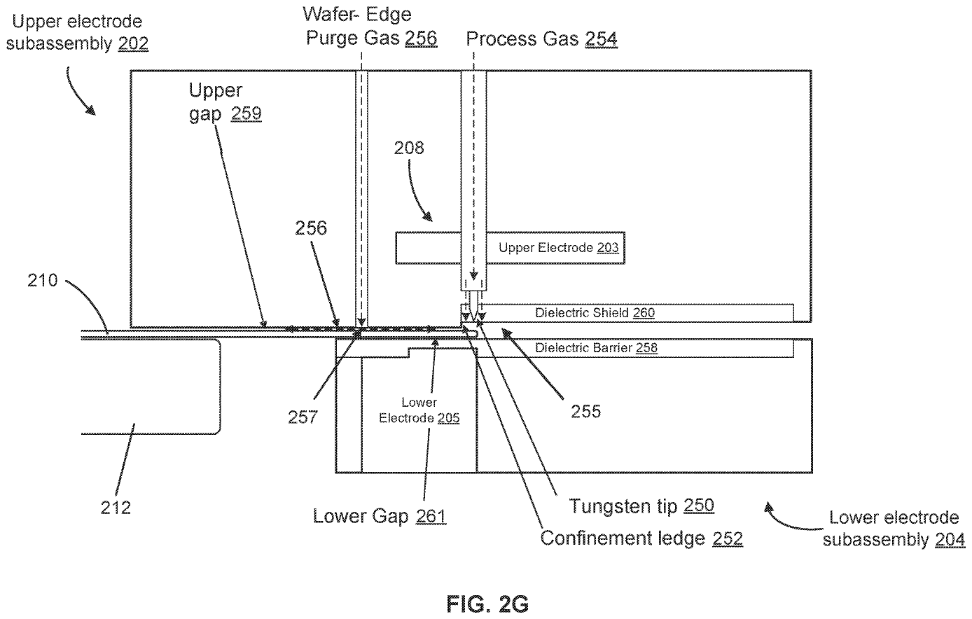

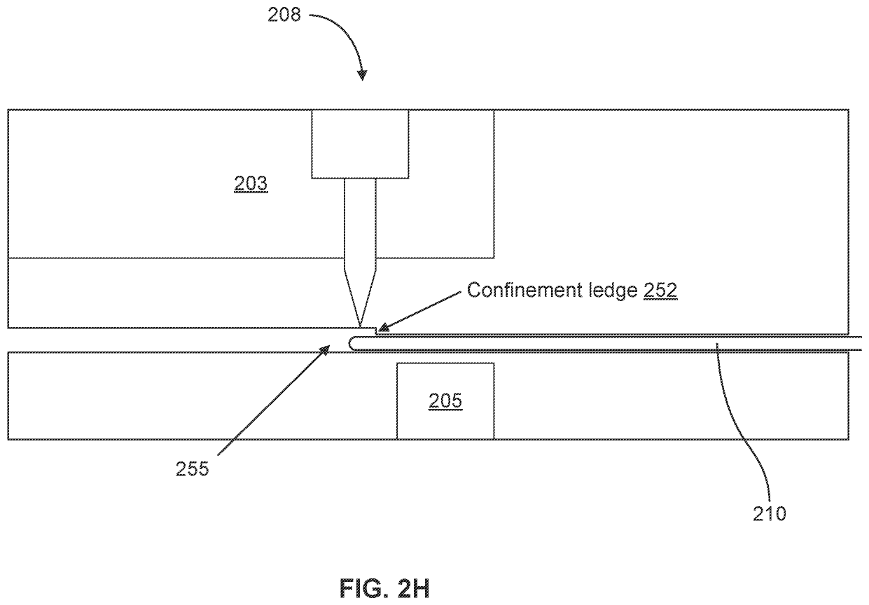

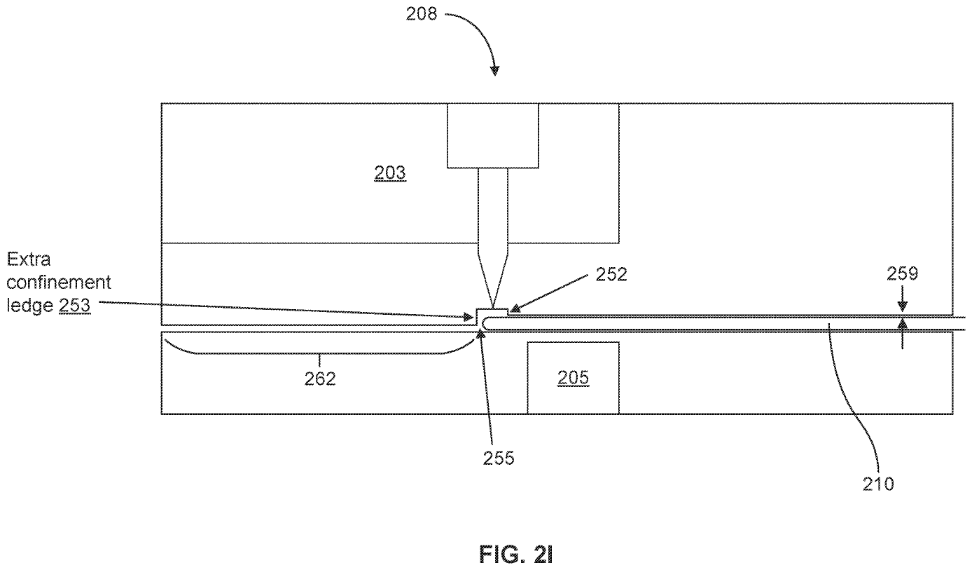

The details of the components of a system using APPJ for EBR will be discussed with reference to FIGS. 1A through 2I. Such a system may be configured to emit plasma radicals that processes a specific location of a semiconductor substrate, e.g., to remove materials at the substrate edge. Using the hardware of such a system, a wafer may be spun on an aligner hardware and through a controlled plasma emitting region, where a plasma source (e.g., a plasma jet) may be configured to etch (or deposit in some configurations) material on a wafer, including on a front side, edge, and/or a back side of the wafer. More particularly, plasma chemistry may etch the region near the wafer edge (or other portions of the wafer). In some embodiments of the present disclosure, rather than using a single jet, an arc-shaped jet that may consist of a single jet region or an array of jets may be employed. In some implementations, such an array may be as simple as many jets distributed across the wafer radius. As alluded to above, alternatively, rather than etch, a suitable choice of plasma feed gases can induce a plasma enhanced chemical vapor deposition of material.

### Edge Bevel Removal (EBR) Using Atmospheric Pressure Plasma Jet (APPJ)

FIG. 1A illustrates an example view of plasma radicals applied to a semiconductor substrate 102, according to some implementations of a material removal system 100 described herein. In some embodiments, the system 100 may include a source subassembly (or subassemblies) 101 that includes an upper subassembly 104, a lower subassembly 106, and a plasma source 108. As noted elsewhere, the plasma source 108 may include at least one plasma jet or at least one nozzle. In some embodiments, the upper subassembly 104 may include an electrode or an electrode assembly. In some embodiments, the upper subassembly 104 may provide aerostatic bearing or aerodynamic bearing. In some embodiments, the lower subassembly 106 may include an electrode or an electrode assembly separate from that of the upper subassembly 104. In some embodiments, the lower subassembly 106 may provide aerostatic bearing or aerodynamic bearing load capacity. Aerostatic bearings use a layer of pressurized gas to provide a low friction load-bearing interface between surfaces. An aerodynamic bearing may form load capacity via the relative velocity of the moving gas between static and moving surfaces (e.g., between a surface of a subassembly and a surface of a spinning substrate). The aerodynamic bearing capacity is beneficial for enabling lower consumption of gas and may allow some operations to perform with no required flow of externally supplied gas.

In some embodiments, the semiconductor substrate 102 may be positioned or placed at a plasma emitting region, between the upper subassembly 104 and the lower subassembly 106, where the components in conjunction (including the plasma source 108) may substantially process an edge 102-e of the semiconductor substrate 102 as the substrate rotates along a selected direction 111 about a central axis 114 of the substrate. More specifically, in some configurations, the plasma source 108 may be substantially confined to the edge of the semiconductor substrate 102 by placement of the substrate edge 102-e proximate to a tip associated with a nozzle or jet of the plasma source 108. The plasma source 108 may be positioned along the upper subassembly 104 (e.g., the tip of the plasma source 108 may be flush with a surface of upper subassembly 104). In some embodiments, a portion of the semiconductor substrate 102 in proximity to the plasma may be sandwiched between one or more surfaces of the upper and lower assemblies 104, 106 for precision gap control. For example, the upper subassembly 104 may include an opening for aerostatic bearing gas to flow onto the upper surface of semiconductor substrate 102. Said proximity may be at the micron level (e.g., range of microns to tens of microns, or under about 100 microns). Advantageously, the resulting micron-level gapping between semiconductor substrate 102 and aerostatic bearing surfaces provides benefits for plasma confinement (e.g., away from inner portions or center of the substrate), edge purge (e.g., removing residues from etched portions), stability of rotating the semiconductor substrate 102, and efficient processing. Advantageously, the plasma source 108 may be enabled to process the edge of the wafer with a short transition from an etched edge to unprocessed film across a defined distance. The edge of the processed semiconductor substrate 102 may have a substantially vertical cut with a sharp transition in thickness. A vertical cut may help prevent a flow of plasma radicals toward the inner portion or center of the substrate.

During processing (e.g., etching), the semiconductor substrate 102 may be spun in the selected direction 111 (e.g., counterclockwise or clockwise) about the axis 114 while secured by other hardware such as an aligner hardware 110. In some cases, the aligner hardware 110 may be configured to translate, traverse, and/or spin (e.g., actuate in X-Y or R-θ-Z directions). In some cases, the aligner hardware 110 may be configured to control another apparatus and cause the other apparatus to translate, traverse, and/or spin. The semiconductor substrate 102 may be secured via the backside, e.g., by vacuum chucking (or in some cases, electrostatic chucking or clamping) with the aligner hardware 110 to secure the semiconductor substrate 102. In some cases, the source subassembly 101 may have a stage 112 coupled thereto for actuation of at least portions of the source subassembly 101 (e.g., in X-Y-Z directions).

In some implementations, the aligner hardware 110 may actuate (e.g., move in X-Y-Z direction) and/or adjust the spin rate, while optionally, radio frequency (RF) power associated with the plasma source 108 may be modulated so as to stop or start etching. An example range of frequency for the RF power may be between about 10 kilohertz (kHz) to about 100 megahertz (MHz). The sharp transition may increase the area on a wafer that yields working die while the specified diameter ensures material removal where desired. Additional details regarding the material removal using the components of assemblies 104, 106 (e.g., electrodes) and plasma source 108 will be discussed in greater detail below with respect to FIGS. 2-2I.

FIG. 1B illustrates an example view of plasma radicals with shield gas directed toward an edge 102-e of a semiconductor substrate 102, according to some implementations of the system 100 described herein. In this configuration, a plasma source 108 may be configured to emit a first gas (e.g., plasma radicals) and a second gas (e.g., shield gas) through respective first and second openings of the plasma source 108. In some implementations, the first gas and the second gas may be emitted from openings other than that of the plasma source 108. The second gas may act as a shield to enable a focused application of the radicals to a specific location (e.g., the edge) of the semiconductor substrate 102. Shield gas may also prevent the plasma radicals from dispersing or recombining with the surrounding air (e.g., as illustrated with respect to FIG. 2F (recombination 221)), enabling focused application of the plasma radicals to the substrate edge 102-e. In the illustrated example operation, as the substrate 102 rotates about an axis 114, different portions of the substrate edge 102-e may be become exposed to plasma radicals.

In some operations, the system configuration may be used to deposit a layer on one or more portions of the substrate 102 (e.g., on the front side) as it rotates, e.g., on the inner portion 102-i or the substrate edge 102-e.

Generally speaking, plasma radicals reaching portions other than the substrate edge 102-e (such as inner portion 102-i) is undesirable, as deposited film or components should remain undisturbed. Hence, in some implementations, the plasma source 108 (e.g., a nozzle thereof) may be positioned or angled toward or away from inner portion 102-i of the substrate 102. The illustrated example in FIG. 1B shows that the nozzle is pointed away from the center of the substrate 102, which may assist with removal of the edge material and prevention of radical accumulation in other parts of the substrate 102. For further assistance, in some implementations, a third gas such as a purge gas and/or aerostatic bearing gas received via a third channel 137 defined adjacent to or otherwise proximate the plasma source 108 (e.g., at another portion of the upper subassembly 104) may be supplied through a third opening proximate the surface of the substrate 102. In some implementations, however, the third channel 137 may be part of (e.g., within the same housing as) the plasma source 108. The third gas may be supplied with sufficient force to keep the plasma radicals directed away from the center of the substrate 102 and toward the substrate edge 102-e and to sufficiently expose the substrate edge 102-e to the plasma radicals. In some cases, the purge gas and aerostatic bearing gas may be supplied through separate third and fourth openings. Further inlets and openings may be present in other configurations.

Advantageously, when used with a relatively high-pressure gas (e.g., at about atmospheric pressure or a specified fraction thereof) compared to traditional approaches in reduced-pressure environment, the material removal system 100 can offer higher reaction product density than is possible with lower-pressure processes. The disclosed concepts offer the advantages and benefits of direct-write capability for high process tunability, very high throughput due to very high etch (or deposition) rate, much lower cost, the ability to easily integrate with etch (or deposition) tools, and if pursued as a standalone implementation, a much lower product footprint. The topology shown in FIGS. 1A and 1B may thereby offer substantial cost savings in hardware compared to current technology based in part on smaller parts volume.

Another advantage of using APPJ in conjunction with EBR is that, although the wafer rotation may be fast (a rate of rotation of, e.g., 60-120 rotations per minute), modulating the RF power to plasma jets associated with the plasma source 108 can be done much faster. Beside control of plasma generation and transport, synchronization of the power and substrate angle or position can produce regions of various film properties to tune the net etch profile as desired, e.g., using on/off or high/low RF power modulation.

FIG. 2 illustrates an overview diagram of a hardware configuration for a material removal system 200, according to some embodiments. In some embodiments, the system 200 may include an upper electrode subassembly 202, a lower electrode assembly 204, a plasma source (not shown), a stage 206 configured for actuation of the upper and/or lower electrode assemblies (e.g., in X-Y-Z directions), and an aligner 212 configured for actuation of a semiconductor substrate 210 (e.g., in X-Y or R-θ-Z). In some implementations, the upper subassembly 104 of FIG. 1 may correspond to or include the upper electrode subassembly 202, and the lower subassembly 106 of FIG. 1 may correspond to or include the lower electrode subassembly 204. The system 200 as shown in FIG. 2 may be agnostic to aerostatic bearing depending on the implementation, however.

In some embodiments, a plasma source may be disposed with (e.g., adjacent, within, or proximate) the upper electrode subassembly 202. In some embodiments, a plasma source may (additionally or alternatively) be disposed with the lower electrode subassembly 204. The plasma source may generate chemically reactive species, e.g., an etchant, which may be provided to portions (e.g., edges or other locations) of the semiconductor substrate 210 in a controlled manner as the semiconductor substrate 210 spins. The spatial distribution of plasma (i.e., an etching profile) may controlled by the configuration of electrodes and gas flow. For example, RF power modulation of upper electrode subassembly 202 and/or lower electrode subassembly 204 may be controlled. Further, flow of first, second and/or third gases as discussed with respect to FIG. 1B may be controlled. Control of these parameters relating to electrodes and gas flow may result in the desired on-wafer etching profile.

By way of background, plasmas may be generated by applying an RF field (e.g., via one or more electrodes) to a gas. The plasma generates reactive species. Reactive species may include electrons, ions, radicals, and neutral species. Ionization of the gas by the RF field ignites the plasma, creating free electrons in the plasma discharge region (e.g., within the plasma source). These electrons are accelerated by the RF field and may collide with gas phase reactant molecules. Collision of these electrons with reactant molecules may form radical species that participate in an etching process or a deposition process.

As the semiconductor substrate 210 spins (e.g., via the aligner 212) while positioned between the upper and/or lower electrode assemblies 202, 204, portions (e.g., edges) of the substrate may be exposed to etchant generated at the plasma source, whereby plasma chemistry and/or modulation of RF power applied to the upper and/or lower electrode assemblies 202, 204 may etch the portions of the substrate 210. In some instances, the inner part of the semiconductor substrate 210, where materials should not be removed, may be protected by a solid object (e.g., a cover) to prevent diffusion of the etchant into the inner area of the wafer. One example of such a solid object may be a confinement ledge as will be discussed with respect to FIGS. 2H and 2I. Thus, at least in part based on physical obstructions (and/or purge gas), materials may be removed only at the wafer edge even if plasma-generated etchant fills the process volume.

However, as noted before, industry requirements for etch rate are increasing, and the necessary precision of the etching profile is becoming narrower. To account for this, positioning of the semiconductor substrate 210 relative to a lower surface of the upper electrode subassembly 202 and relative to an upper surface of the lower electrode subassembly 204 may be precisely controlled. More specifically, the gap between the two assemblies may be defined. In some cases, this requires highly skilled operators or engineers and takes a long period of time to optimize the hardware configuration. The solid object or cover may also need to be re-designed to change the etching profile. Once the hardware is set up and the chamber is closed, it becomes difficult to tune the etching profile and etching width without opening the chamber.

Therefore, the present disclosure may utilize the fact that diffusivity of gas is smaller at higher pressures. For instance, at a higher pressure of gas, such as atmospheric pressure, the diffusivity of gas is 760 times lower than a typical lower-pressure operating condition. Thus, etching profile may be adjusted by controlling a gas curtain, not mechanical hardware. Additionally, a point source may be chosen with a wafer spinner over a ring-shaped source with a fixed pedestal. This may reduce or minimize non-uniform etching around the wafer bevel because wafer rotation smooths out spatial and temporal plasma fluctuation. Moreover, atmospheric-pressure EBR does not require vacuum pumps, which may reduce the mechanical footprint and the cost. Hence, configurations of the system 200 may advantageously enable etching materials to be applied only at the wafer edge without a vacuum system, which may reduce the cost and the system footprint.

However, it will be recognized that the system 200 may also be configured to apply etchants at different portions of a wafer (e.g., other than the edge) for a desired etching profile for other applications, such as compensating for existing wafer bow. For instance, the gap between electrode assemblies 202, 204 may be extended and/or the protective solid object (e.g., cover) may be absent or placed such that the aligner 212 may move the wafer “deeper” into the assemblies, allowing etching at portions other than the edges (e.g., inner portion 102-i as shown in FIG. 1B).

FIG. 2A illustrates a cross-sectional overview diagram of a hardware configuration for a material removal system 200, according to some embodiments. In some embodiments, upper electrode subassembly 202, lower electrode subassembly 204, and stage 206 may be configured to receive a semiconductor substrate 210 that is actuated via an aligner 212 may be used as discussed above with respect to FIG. 2. In some embodiments, the upper electrode subassembly 202, lower electrode subassembly 204, and stage 206 may be part of a source subassembly 101 as described with respect to FIG. 1A. In some embodiments, the aligner 212 may include a chuck 213, one or more pins 214, and/or an alignment sensor 215.

The aligner 212 may include various components that are configured to securely hold and actuate the semiconductor substrate 210 to, e.g., raise, lower, insert into source subassembly 101 (e.g., between the upper and lower electrode subassemblies 202, 204). In some implementations, the aligner 212 may be used to adjust the position of the substrate 210 on the chuck 213 such that the wafer spins with minimized eccentricity. The substrate 210 may also be served or actuated (e.g., in x- or y-direction toward or away in an orthogonal direction to upper and lower electrode subassemblies 202, 204) as the substrate 210 spins using the measured eccentricity to minimize the edge motion under, e.g., a plasma jet of the upper electrode assembly substrate 202.

Those of ordinary skill in the art will recognize various configurations of securing the substrate 210 with respect to the chuck 213. In some embodiments, the chuck may be a vacuum chuck 213. That is, the aligner 212 may securely hold the substrate 210 with sufficient holding force using suction of the vacuum chuck. Vacuum chucks are simple, convenient, and cost-effective to implement. In fact, vacuum chucking may be especially appropriate for processing occurring at atmospheric pressure according to the present disclosure, since, in a vacuum chamber where pressure would already be dramatically lower than atmospheric, there would not be an ability to vacuum chuck the substrate 210. In a vacuum environment, or in the atmospheric environment, other types of chucking may be used, such as below.

In alternate embodiments, the chuck 213 may be an electrostatic chuck (ESC), which may securely hold the substrate 210 using electrostatic force. In some cases, such an ESC may be a bipolar ESC having a pair of complementary and coplanar clamping electrodes (which may be embedded within a pedestal structure) which generate the electrostatic force. In some cases, the ESC may be a monopolar ESC having one clamping electrode, where the one electrode may have a voltage applied thereto and an opposite charge may be induced in the substrate 210 using, e.g., an opposing electrode above the substrate 210 (or, in certain implementations, a plasma generated above the substrate 210, e.g., if within a process chamber).

In some embodiments, the chuck may be configured to move in multiple degrees of freedom. One example of a degree of freedom is translation. Another example is rotation. The chuck may be configured to translate along an x-axis, a y-axis and/or a z-axis, e.g., using an actuator, causing the substrate 210 to move in the corresponding direction(s). In addition, the chuck may be configured to rotate with respect to the z-axis, causing the secured substrate 210 to rotate at the same rate of rotation (e.g., 60-120 rotations per minute, e.g., 100 rotations per minute). In some implementations, the chuck may be secured to a separate stage (or separate actuator), e.g., a stage (not shown) that is configured to translate (along the x-axis, the y-axis and/or the z-axis) and/or spin or rotate (with respect to the z-axis), or cause the chuck to translate, spin and/or rotate. Spin about the z-axis may allow the nozzle to cover the entirety of the circumference of the substrate 210 (e.g., along its outer edge), and with control of the state of the nozzle (high/low or on/off), various etching patterns can be formed. In some implementations, the nozzle housing or the nozzle may be configured to rotate or tilt or angle about the x and/or y-axes so that the nozzle can cover a greater portion of the substrate 210 when the substrate 210 is positioned over the nozzle. In some implementations, the position of the nozzle may be varied with respect to the nozzle housing. For example, the nozzle may be repositioned along the x-axis, y-axis, z-axis, radial (r) direction, and/or an angular (θ) direction. Angular repositioning may cause tilting of the nozzle with respect to the nozzle housing, but the nozzle housing may remain in the same angular position or tilt.

In some embodiments, the pins 214 may be ceramic, metallic, or elastomer pads or raised platforms configured to hold the semiconductor substrate 210 when the substrate is not being secured by the chuck 213. For example, the semiconductor substrate 210 may be placed onto the pins 214. In some cases, the substrate may be placed in a specific position (e.g., relative to the chuck), or orientation or direction, according to a wafer notch or marker on the substrate and/or position sensing by the alignment sensor 215. Proper placement of the semiconductor substrate 210 on the pins 214 may allow the chuck 213 to secure the semiconductor substrate 210, e.g., using an approach described above (e.g., vacuum chucking or ESC). The central axis of the semiconductor substrate 210 may overlap with the central axis of chuck 213 when the substrate 210 is properly aligned. In some implementations, the alignment sensor 215 may use one or more optical sensors (e.g., laser) or visual sensors for imaging (e.g., camera) for the aforementioned positioning sensing or to measure wafer eccentricity. The alignment sensor may be used to sense the location of the wafer notch, and this information may be used to account for different process conditions and/or wafer positioning that may be needed in the proximity of the notch to get desired etch results.

Additional details follow regarding the relevant systems and components outlined above.

FIG. 2B illustrates an expanded, vertical cross-sectional view of a nozzle of a plasma source 208 that may be used in the system 200, in some implementations. Plasma source 208 may be an example of the plasma source 108. The plasma source 208 may include a first electrode 233 defined in approximately in the center of the nozzle. A dielectric material 238 may be disposed to surround the first electrode 233 so that a first channel 235 is defined between the first electrode 233 and the dielectric material 238. The first channel 235 may be connected to a first gas source (FIG. 1B) through a first inlet 231 defined at a first end, and to a first opening 242 at a second end defined proximate to the top of the nozzle. The first channel 235 may be configured to receive a first gas from the first gas source through the first inlet 231. A second electrode 234 may be embedded within the dielectric material 238 and surround the first electrode 233. The dielectric material 238 may act as a barrier to metal surfaces so as to prevent arcing and metal contamination when RF power is applied.

In some implementations, the first gas may be an etchant gas. In some cases, the first gas may be a reactant gas or a mixture of gases, including, e.g., oxygen-based, fluorine-based, hydrogen-based, chlorine-based chemistries, or another etchant precursor and/or an inert carrier gas such as argon, neon, or helium. The inert gas may be used to carry plasma radicals of the etchant through the first opening 242. It should be noted that the aforementioned examples of gases are provided as mere examples and should not be considered restrictive. Where the system 200 is used for edge bevel removal, depending on the type of films (i.e., residues) of the edge of a substrate which is being targeted for removal, the carrier gas may be any stable, inert gas such as argon, neon, or helium, and the etchant gas may contain oxygen, fluorine, chlorine, or some other halogen, or hydrogen. In some cases where deposition is desired with the APPJ system, the first gas may be a mixture of a deposition gas and a carrier gas.

As noted above, the RF power may be modulated so as to vary the emission of plasma radicals as the substrate 210 spins, thereby creating a desired pattern of etching, e.g., at the front side of the substrate 210. Such modulation may be performed based on signals generated by a controller, logic, a differential drive, etc. that is coupled to the plasma source, upper electrode subassembly 202 and/or lower electrode subassembly 204.

Further, a controller or logic may further control one or any combination of the following parameters: rate of rotation of the substrate, nozzle position relative to the substrate (in, e.g., x, y and/or z-axis), and plasma parameters (such as plasma power, RF frequency, gas flow rate, gas composition, and/or gas pressure). In some implementations, plasma power may vary between on and off. In some implementations, plasma power may vary between high and low RF power, rather than on/off. Other parameters affecting etching may include residence time of a nozzle's jet emission at any location on the wafer. Any of these parameters can impact the etching of one or more layers, e.g., at the edge or other portions of the substrate 210. These parameters may be controlled while the substrate 210 is rotated or where the nozzle is positioned with respect to the substrate 210 (including in the X-Y-Z space, radially, and azimuthally). In some implementations where multiple nozzles are used or included in the assembly (e.g., upper electrode subassembly 202), each of the multiple nozzles may be separately controlled.

The dielectric material 238 disposed within the nozzle may further define a second channel 236 between the dielectric material 238 and an outer wall of the nozzle 239. The second channel 236 may be coupled to a second gas source (FIG. 1B) through a second inlet 232 defined at a first end, to receive a second gas, and a second opening 243 is defined at a second end defined at the bottom of the nozzle. The second opening 243 may be defined adjacent to and surround the first opening 242. The second opening 243 may be a single opening or a plurality of openings that surround the first opening 242 (two are depicted in FIG. 2B). The second gas may be an inert gas, such as argon, neon, or helium. The second gas may be curtaining gas, such as nitrogen or air. The second channel 236 may create a separate gas path for the second gas, and the second opening 243 in the top of the nozzle may direct the second gas to flow up without perturbing the plasma radicals flowing through the first opening 242. The second gas exiting the second opening 243 may act as a shield for the plasma radicals mixed with the carrier gas exiting the first opening 242 by encircling the mixture of plasma radicals and the carrier gas.

It will be appreciated that an additional third inlet or channel (not shown) proximate to the first inlet 231 and/or the second inlet 232 may supply a third gas such as a purge gas and/or aerostatic bearing gas through a third opening (not shown). Third channel 137 of FIG. 1B may be an example of the third inlet or channel. In some implementations, the third gas may be supplied with sufficient force to keep plasma radicals directed away from the center of the substrate 210 and toward the substrate edge and to sufficiently expose the substrate edge to plasma radicals. In some cases, the purge gas and aerostatic bearing gas may be supplied through separate third and fourth inlets and openings. Further inlets and openings may be present in other configurations.

Referring again to FIG. 2B, in some implementations, the second electrode 234 embedded in the dielectric material 238 may be oriented in parallel orientation to the first electrode 233 disposed approximately in the center of the nozzle. In some alternate implementations, the second electrode 234 embedded in the dielectric material 238 may be oriented perpendicular to the first electrode 233, at least in part. In yet alternate implementations, the second electrode 234 may be shaped to follow a contour of the dielectric material 238 and may be oriented so as to be parallel to the first electrode 233. Irrespective of the orientation, the second electrode 234 may be disposed at a pre-defined distance from the first electrode 233, wherein the pre-defined distance may be determined to enable generation of plasma of the first gas received in the first channel 235. In some implementations, the first electrode 233 may be made of metal. In some implementations, the first electrode 233 and the second electrode 234 may be made of same material. In some implementations, the first electrode 233 may be made of different material than the second electrode 234. The material used for the second electrode 234 may be chosen so as to withstand high temperatures. In some approaches, the material used for the second electrode 234 may be chosen to have a coefficient of thermal expansion (CTE) that matches the CTE of the dielectric material 238 in which the second electrode 234 is embedded. In some approaches, the first and the second electrodes 233, 234 may be made of any one of tungsten, molybdenum, iridium, rhenium, or platinum, and the dielectric material 238 may be made of any one of aluminum nitride, aluminum oxynitride, silicon nitride, aluminum oxide, or yttrium oxide. In some implementations, the dielectric material 238 and/or the first electrode 233 may be cooled using one or more cooling elements (not shown). In some cases, the cooling element may be disposed in a region that is proximate to the second electrode 234.

In some implementations, the first electrode 233 disposed proximate to the center of the nozzle may be coupled to the aforementioned RF power source, and the second electrode 234 may be grounded via a match network. In some other implementations, the first electrode 233 may be grounded and the second electrode 234 may be coupled to the RF power source via a match network. In yet other implementations, the first electrode 233 and the second electrode 234 may be coupled to the RF power source via a match network, and neither the first electrode 233 nor the second electrode 234 may be grounded.

In some configurations, a differential voltage may be applied to the first electrode 233 and the second electrode 234. As an illustrative example, for an input voltage of 200 volts (V), the voltage applied to the first electrode will be +100 V and the voltage applied to the second electrode will be −100 V (i.e., each electrode may be provided with one half of the input voltage). In some instances, a differential drive (not shown) may be coupled to the RF power source and used to switch the RF power input between the two electrodes (first electrode 233, second electrode 234). In some implementations, the differential drive may be an isolation transformer with secondary windings used to provide the differential voltage.

The topology of the nozzle may be defined so as to supply high density plasma radicals to the substrate 210 in order to achieve high-precision etching (or deposition in certain cases). In some example implementations, the flow rate of the reactant gas in the first gas may be defined to be between about 100 standard cubic centimeters per minute (sccm) and about 300 sccm, and the flow rate for the carrier gas flow may be defined to be between about 1,000 sccm and about 30,000 sccm. In some embodiments, the pressure of the plasma generated in a region between the upper and lower electrode assemblies may be above a threshold, e.g., at least 200 torrs (Torr). In some implementations, the plasma pressure may be about 760 Torr (atmospheric). In some implementations, plasma pressure may be some other fraction of atmospheric.

The topology of the nozzle may provide an efficient and effective way of processing the substrate 210 using a simple process chamber that includes minimal hardware. The plasma can be generated remotely and provided to the edge or other portions of the substrate 210. In addition to the first and the second gas being applied to the substrate 210, a third gas may also be provided from a third channel defined adjacent to the nozzle. The third gas may act as a gas curtain pushing the first gas enveloped in the second gas away from the center of the wafer so as provide focused application of the plasma radicals, whether at the wafer edge or at a defined radius from the center. The simple design may allow the process chamber to be kept lightweight and small, enabling the process chamber to be stacked on other existing modules (e.g., loadlock), leaving no additional footprints.

In some implementations, there may be ‘n’ number of nozzles (where ‘n’ is an integer) within a housing for the nozzle, at least some of the n nozzles providing the plasma radicals simultaneously to cover a larger area of the substrate 210 or its edge. In some implementations, the nozzle housing may include 3 or 5 or 7 or 9 nozzles disposed proximate to one another. In some implementations, the ‘n’ nozzles may be disposed along an arc defined in the nozzle housing. The arc may be defined to match the curvature of the substrate edge. In some implementations, the ‘n’ nozzles may be disposed in a substantially linear fashion rather than an arc that matches the curvature of the substrate edge. In some cases the linear nozzles may be spread in a radial direction such that the nozzles may enable etching at different radial positions along the substrate. Although various implementations have been described herein with reference to the system 200 using a nozzle, the implementations are not limited to nozzle operation, and other non-nozzle tools or parts may also be engaged for processing the substrate 210.

In certain embodiments, the housing for the nozzle and/or the nozzle(s) themselves may be configured to actuate in the z-axis (e.g., vertically) and/or radially depending on the distance to a portion of the semiconductor substrate 210 such as the edge thereof. For example, the housing may actuate within the upper electrode subassembly 202 and/or the nozzle(s) may actuate within the housing. The distance to the portion of the semiconductor substrate 210 may be measured using, e.g., one or more optical sensors (e.g., laser). Based on any variation that exists in the distance between the housing or the nozzle to the semiconductor substrate 210 (which may occur because of unevenness, bow, eccentricity, etc. of the substrate), the housing or the nozzle(s) may be actuated (e.g., by a controller) correspondingly by the measured distance, thereby keeping the distance constant.

FIG. 2C is a cross-sectional diagram showing the upper electrode subassembly 202, semiconductor substrate 210 (e.g., wafer), and lower electrode subassembly 204, according to some embodiments. As can be seen, the wafer is positioned (e.g., inserted) between surfaces of the upper and lower electrode assemblies 202, 204, and the edge of the semiconductor substrate 210 (wafer edge) is placed below the plasma source 208.

The plasma source 208 may generate radicals. In some configurations, the generated radicals may be transported to the wafer edge. Radical generation may involve application of RF power at the upper electrode subassembly 202 only. This approach may be referred to as an “indirect” plasma generation. In some configurations, however, the radicals may be generated directly on the edge of the semiconductor substrate 210, e.g., via application of RF power with both the upper and lower electrode assemblies. This approach may be referred to as a “direct” plasma generation.

FIG. 2D illustrates indirect plasma generation and transportation, wherein RF power may be applied to the upper electrode subassembly 202 so that radicals are generated within the plasma source 208. In some embodiments, an inductively coupled plasma (ICP) source may be used, which is a type of plasma source in which the energy is supplied by electric currents which are produced by electromagnetic induction, that is, by time-varying magnetic fields. The plasma radicals are generated remotely from the material to be processed (e.g., layers or film on semiconductor substrate 210). The generated radicals may then be emitted from the plasma source 208 and transported with carrier gas via a nozzle of the plasma source 208. Portions of a semiconductor substrate 210 (e.g., wafer edge) may be processed (e.g., etched) using the radicals that are transported there.

FIG. 2E illustrates direct plasma generation, wherein RF power may be applied to the upper electrode subassembly 202 and the lower electrode subassembly 204 so that radicals are generated directly on portions of the semiconductor substrate 210 (e.g., wafer edge). In some embodiments, a capacitively coupled plasma (CCP) source may be used. Since etchants are generated directly on the wafer edge, transportation does not occur, advantageously reducing losses in radicals, e.g., via recombination 221 of radicals (e.g., O+O₂→O₃) as shown in FIG. 2F, and thereby increasing etch. Such recombination and losses may still occur in indirect plasma generation and transportation, specifically during transportation, since radical oxygen atoms may react with molecular oxygen.

As illustrated in FIG. 2F, examples of factors may be involved in processing a wafer edge using the plasma source 208 include: (1) radical generation, (2) transportation of radicals, and (3) surface reaction. Radical generation may include breakdown of gas species such as molecular oxygen (O₂→O+O).

Factors influencing radical generation may include O₂ concentration (including in carrier gas), plasma density and electron temperature, and carrier gas used. In some implementations, O₂ concentration may be less than 10% in the carrier gas. ICP in high pressure may be used to create optimum plasma density and electron temperature. The gas pressure in the reactor can be atmospheric (about 760 Torr), or it can be lower than atmosphere, i.e., a fraction of atmospheric (e.g., about 200 Torr or above). In some embodiments, process gas and carrier gas may be introduced together, and the process gas and the inert gas may have a total pressure of at least about 200 Torr. Higher pressure may contribute to higher etch rate in EBR. Process gas may include, for example, reactant gas or etchant gas that plasma radicals are generated from. Carrier gas may be an inert gas, e.g., helium (He), neon (Ne), or argon (Ar).

Factors influencing radical transportation may include distance to wafer, gas flow, and recombination conditions. In some implementations, a CCP source may be used, such that distance to the wafer edge is virtually none and no transportation is involved. For example, the direct plasma generation approach as described with respect to FIG. 2E may be used. A higher gas flow rate may be used (e.g., to prevent etching of areas that should not be etched). For recombination, a O₂ pressure of less than 10% in inert gas may be specified, for example.

Surface reaction may involve etching of the wafer edge. Factors influencing surface reaction may include temperature, where a higher temperature may be used to effectuate etching. Gas composition may influence etch rate as well, where higher O₂ concentration in the purge gas and/or lower O₂ concentration in the process gas was found to have a higher etch rate.

FIG. 2G illustrates a closer view of hardware configuration of material removal system 200, according to some embodiments. A semiconductor substrate 210 may be supported and secured by an aligner 212 (including, e.g., a chuck) and inserted into a gap between the upper electrode subassembly 202 and a lower electrode subassembly 204. In some embodiments, the plasma source may include a tip 250, e.g., at a nozzle of the plasma source. Materials for the tip may include tungsten, or in some implementations, other metals such as molybdenum, iridium, rhenium, or platinum, in some implementations. In some embodiments, the edge of the semiconductor substrate 210 may be confined at least in part by a solid object such as a confinement ledge 252. The confinement ledge 252 may be configured, positioned, and shaped such that it confines and/or at least partially prevents etchant, materials, gas, plasma, etc. from diffusing into the inner area of the wafers.

In some embodiments, the system 200, specifically the aligner 212, may further include a chuck or be configured to interact with a chuck. In some embodiments, the chuck may comprise a stem portion and a chucking portion that interfaces with the substrate 210. The stem portion may be sufficiently narrow (e.g., diameter of stem portion is significantly smaller than, e.g., less than half of, diameter of substrate 210) to accommodate movement of the chuck into the gap between the upper and lower electrode assemblies 202, 204 such that the plasma source and the tip 250 (or in some implementations, multiple tips or nozzles) may have access to at least the edge of the substrate 210. One example diameter for the chuck may be 10 inches.

Returning to FIG. 2G, one or more process gases 254 may be provided to the plasma source. In different implementations, processes gases 254 may include reactant or etchant gases such as oxygen and carrier gases (e.g., inert gases such as helium, neon, or argon). The process gases 254 may be excited to a plasma state (e.g., via RF power application using upper and/or lower electrodes) for direct plasma generation, or indirect plasma generation and transportation. The generated plasma radicals may be confined to a vacuum or process volume 255, at least in part based on the confinement ledge 252 and other components of the system (e.g., walls present across the confinement ledge 252).

Process gases 254 may thereby be used to generate plasma at the plasma source at a certain pressure and expelled through the tip 250. In some embodiments, the plasma may be atmospheric-pressure plasma (also known as normal-pressure plasma), which has a pressure that approximately matches that of the surrounding atmosphere. In some embodiments, the plasma may have a pressure of at least about 200 Torr or at least about 300 Torr. This is in contrast to some traditional EBR applications where etchants are generated by low-pressure plasmas. However, performance limits (e.g., low etching rate, high diffusivity) of low-pressure etchants and width of the etching profile (e.g., control of etchant delivery, accuracy and location of where etchant is delivered) may be improved using higher-pressure plasma. Nonetheless, pressure of plasma may be modified depending on implementation of the system disclosed herein and its use application. In fact, adjusting the plasma pressure is easily done for a user or operator, and obviates the need to optimize or redesign the hardware configuration when an adjustment to the etching profile and etching width is desired.

In addition, one or more purge gases 256 may be provided through an opening 257 to remove the etched edge products from the EBR operation. Examples of purge gases 256 may include different ratios of etchant and carrier gas or inert gases. In some cases, the purge gases 256 may include nitrogen or air. The upper gap 259 may be designed to be small enough to substantially suppress plasma light-up where the gap is small, but the combination of etchant and carrier gas exiting to the plasma lit-up region may contribute to the etch profile and etch rate. In some applications, the desired etch profile may transition fast from nominally no etch to fully etched film and can be optimized by the ratio of etchant and carrier gas. Purge gases 256 may be emitted throughout an upper gap 259 at the upper portion (e.g., at the front side) of the semiconductor substrate 210. In some configurations, purge gases 256 may be emitted throughout a lower gap (not shown) at the lower portion of the semiconductor substrate 210, e.g., via the lower electrode subassembly 204. The semiconductor substrate 210 being processed by the material removal system may be very close to a dielectric surface (e.g., dielectric shield 260) of the upper electrode subassembly 202 and a dielectric surface (e.g., dielectric barrier 258) of the lower electrode subassembly 204. Hence, the upper gap 259 may be very small. In some cases, the upper gap 259 may be about 3 mils (about 0.003 inches or approximately 76.2 microns). In some cases, the upper gap 259 may be about 100 microns or less (e.g., microns to tens of microns). A lower gap 261 may exist between the semiconductor substrate 210 and the lower electrode subassembly 204. In some implementations, the lower gap 261 may be of a similar size as the upper gap 259. In some implementations, the lower gap 261 may have a small (e.g., under about 10 microns) but non-zero distance.

It is especially important to select a sufficiently narrow size for the upper gap 259, between the semiconductor substrate 210 and the upper electrode subassembly 202. Substantial stiffness may be provided between the semiconductor substrate 210 and the dielectric surface (e.g., dielectric shield 260) when upper aerostatic bearing gas or purge gas 256 is flowed in a small gap in the upper gap 259. The orifice of the tip 250 may be designed to have a choked flow between the outer diameter of the orifice and the small gap to the wafer. The viscous forces through the small gap may provide a pressure that balances with pressure at the orifice exit. If the size of the gap were increased, viscous forces will reduce, thereby lowering the pressure at the orifice exit, causing flow to increase. At the same time, the force between the dielectric and the substrate varies with gap and thereby a stiffness exists. The purge gas 256 may contribute to the process results by suppressing plasma from entering the upper gap 259, which may ensure that etching does not diffuse too far into inner portions of the wafer (e.g., 102-i), which can enhance reaction product density in the area around the edge of the wafer. Therefore, another consideration can be independent control of the gas flow, e.g., to configure the purge gas 256 and/or aerostatic bearing gas to supply the desired amount of gas, e.g., at a flow rate of 0.1-100 standard liters per minute (slm) nominally exiting into the upper gap 259 to optimize the processing of the wafer edge. The aerostatic bearing surface area, orifice array spacing, orifice diameters, and pressure are selected to produce sufficient force and stiffness, at a controlled range of gap such that the spinning substrate 210 does not contact the aerostatic bearing surfaces in the presence of out-of-plane wafer motion. Out-of-plane motion may be caused by reasons including imperfection in the aligner 212 motion, substrate 210 distortion, including distortion that is thermally induced by the plasma jet, and substrate 210 thickness variation.

In other words, the aerostatic bearing may keep the substrate 210 on a relatively fixed plane and reduce friction against hardware surfaces as the substrate rotates. As the substrate 210 rotates, chemically reactive species such as etchant generated at the upper electrode subassembly 202 may be applied to the edge or other portions of the substrate 210. For direct plasma generation, RF voltage may be applied between the upper electrode 203 and the lower electrode 205, and a plasma can be generated in a relatively small and confined region around the wafer edge (e.g., within the process volume 255). In some etching implementations, the plasma chemistry may be selected to have volatile reaction products with the film to be etched. As examples, oxygen radicals can be specific to carbon (C) or carbon-based film, while fluorine (F) radicals may be selected against molybdenum (Mo) or tungsten (W) materials for removal. Appropriate reactants may be selected to target the metal or material to be etched. For deposition, the plasma chemistry may be selected to have deposition products for plasma enhanced chemical vapor deposition (PECVD) or plasma enhanced atomic layer deposition (PEALD). Example precursors for silicon dioxide deposition include silane and tetraethoxysilane (TEOS). Deposition gas for silicon nitride may include silane, nitrogen, and ammonia as examples. An example precursor for tungsten deposition includes tungsten hexafluoride (WF₆). These examples are illustrative and do not exclude other chemistries selected for specific film compositions.

In some example operations, the distance or gap between the upper electrode subassembly 202 and the lower electrode subassembly 204 may be set to or adjusted (e.g., via z-axis movement of the electrode assemblies and/or substrate 210 via, e.g., the chuck) so that even a bowed substrate may be received without touching the surface of the upper and lower electrode assemblies.

In some implementations, a plasma jet or plasma jet emitter of the nozzle may be rasterized over the surface of the substrate 210. Multiple nozzles (e.g., an array or group of 2-10 nozzles or plasma jets) may perform the rasterization. In some variants, the multiple nozzles may be in a fixed position with respect to one another, and in some cases, multiple plasma jet emitters may be disposed within a given nozzle.

In some implementations, the material removal system 200 may include an exhaust (not shown) to promptly remove plasma radicals and residues released from the substrate 210 and/or its edge during or after EBR operations performed with the system 200. Prompt removal of the residues and radicals ensures that the residues do not contaminate the substrate surface and that the radicals do not damage any formed devices present on the substrate surface (e.g., on the frontside).

In some implementations, upper and lower electrodes may be vertically offset and/or horizontally offset from each other such that they are not on the same vertical axis. In such cases, electric field lines may be forced to pass through the edge region of the semiconductor substrate 210 processing (e.g., etching) is desired.

Referring now to FIG. 2H, a cross-sectional view of the plasma source 208 with a confinement ledge 252 is illustrated. In some embodiments, as alluded to above, the confinement ledge 252 may be an additional physical feature that may be part of (e.g., unitary) the upper electrode subassembly 202 or otherwise incorporated with the system hardware. In some configurations, the confinement ledge 252 may be associated with (e.g., adjacent or proximate to) the plasma source 208. In some cases, the confinement ledge 252 may be brought out to define an exclusion region on the semiconductor substrate 210 where plasma may be substantially suppressed under the confinement ledge 252.

In some implementations, as shown in FIG. 2I, an extra confinement ledge 253 may be present. Similar to confinement ledge 252, the extra confinement ledge 253 may be configured to further suppress the volume where plasma can light up. For example, confinement ledge 253 may confine and/or at least partially prevent etchant, materials, gas, plasma, etc. from diffusing out of process volume 255. Allowing plasma in a localized region (e.g., process volume 255) where the edge of the semiconductor substrate 210 is while suppressing plasma in volumes or regions 262 where it may not be useful may improve the efficiency of the plasma-generating components (e.g., plasma source 208, upper electrode subassembly 202, and/or lower electrode subassembly 202) and may prevent processing in areas that are not wanted. The small gaps 259 that allow aerostatic bearing may also enhance the effectiveness of the confinement, e.g., by providing stiffness and pressure that balances the pressure at the orifice exit of the plasma source 208, suppressing plasma generation in the upper gap 259 where processing is not desired at the inner portions of the semiconductor substrate 210, controlling the etching profile and etching width.

Ledge features such as the confinement ledge 252 and/or the extra confinement ledge 253 may prevent other atmospheric gases (e.g., nitrogen) from entering the process volume 255, further isolating the plasma that is processing the wafer edge.

Accordingly, by leveraging the various physical configurations described above, reactive species (e.g., etchant) can be substantially confined using an aerostatic bearing at a narrow gap between the wafer and the hardware (e.g., upper electrode subassembly) to process the edge of a spinning wafer. By modulating RF power, by actuating the upper and/or lower electrode assemblies (e.g., in X-Y-Z directions), and/or by actuating the wafer (e.g., in X-Y directions), precise positioning and processing of the wafer is possible. Rapid modulation of RF power (which as noted above can be faster than wafer rotation) and/or change in emission or flow rate of generated plasma while the wafer is spinning may allow processing (e.g., etching) at desired locations, e.g., to remove unwanted materials from the wafer edge. Processing of regions other than the edge such as inner portions may be further possible based on wafer actuation (e.g., in X-Y directions to insert it deeper into the narrow gap). In some cases, deposition may be performed, e.g., on the front side of the wafer to undo an overetch or effectuate bow compensation, or on the back side of the wafer to effectuate bow compensation.

As noted above, the RF power may be modulated so as to vary the emission of plasma radicals as the substrate 210 spins, thereby creating a desired pattern of etching. Such modulation may be performed based on signals generated by a controller, logic, a differential drive, etc. that is coupled to the plasma source 208, upper electrode, and/or lower electrode.

Moreover, as mentioned or will be mentioned elsewhere herein, the controller or logic may further control one or any combination of the following parameters: rate of rotation of the substrate, tip position relative to the substrate (in, e.g., x, y and/or z-axis), and etching rate parameters (such as plasma power, RF frequency, gas flow rate, gas composition, and/or gas pressure).

In some operations, a parameter to control in the etching profile may include the radial position where the material removal occurs. This may result in a specified radius (or diameter) of materials being treated on the substrate 210. The radius or diameter may be selected or specified on a wafer-by-wafer basis as it comes in. In some implementations, a material radius may be defined to be within a range between about 148 to 148.5 mm (or a difference of 0.5 mm). In some implementations, a material radius may be defined to be within a range between about 147 to 148 mm (or a difference of 1.0 mm). In some cases, the material radius may be defined to be without a range with a substantially vertical cut. This range of material radius may be made narrow with a precise margin (e.g., within 0.1 mm) such that the transition of the thickness of the film is sharp, creating a vertical cut that may help prevent a flow of radicals toward the inner portion or center of the wafer.

Some parameters may influence the manner of deposition as well. Such deposition parameters may include: plasma power (on/off; or high/low between high and low RF power, rather than on to off), RF frequency, gas flow rate, gas composition, gas pressure, distance between nozzle and substrate, and substrate temperature. Any of these deposition parameters can impact the local thickness and/or internal stress of the backside layer. These parameters may be controlled while the substrate is rotated or where the nozzle is positioned with respect to the substrate (including in the X-Y-Z space, radially, and azimuthally). In implementations where multiple nozzles are used or included in the nozzle housing, each of the multiple nozzles may be separately controlled.

### Methods

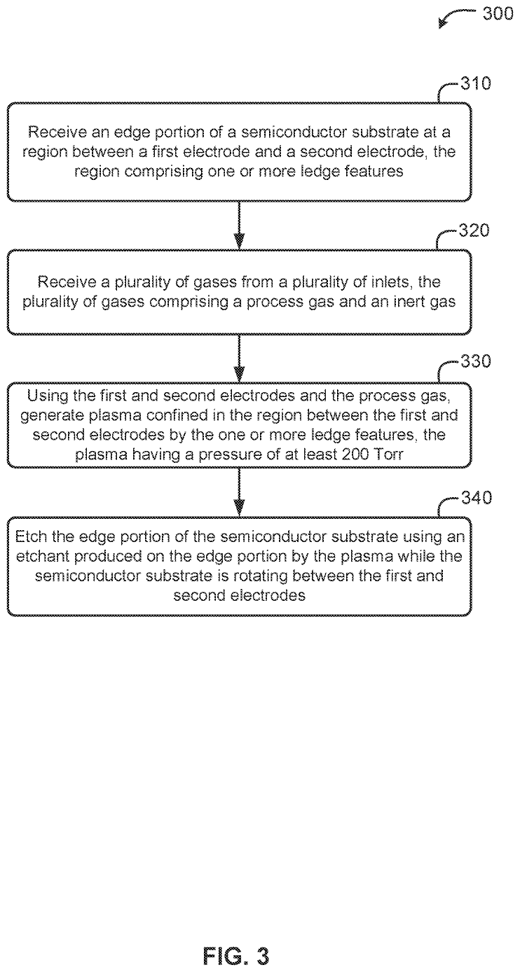

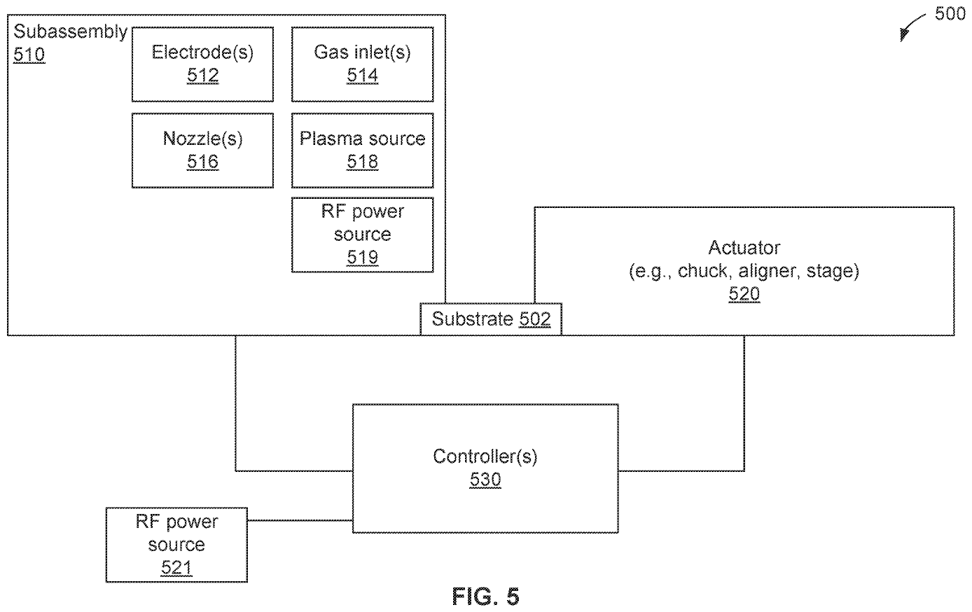

FIG. 3 is a flow diagram illustrating a method 300 of processing a semiconductor substrate, according to some embodiments. The substrate may have a frontside, the frontside having electronic device features fabricated thereon. One or more blocks of the method 300 may be performed by or caused by an apparatus or system controlled by a computing device. Such a system may include various hardware components, such as one or more electrodes, RF power supply, and/or actuator (e.g., stage, aligner) as described above. Structure for performing the functionality illustrated in one or more of the blocks shown in FIG. 3 may include hardware and/or software components of such apparatus or system, or computing device, such as, for example, a controller or a computer-readable apparatus including a storage medium storing computer-readable and/or computer-executable instructions that are configured to, when executed by a processor apparatus, cause the processor apparatus to perform the operations. Example components of the apparatus or system are discussed with respect to FIG. 5 below.

It should also be noted that the operations of the method 300 may be performed in any suitable order, not necessarily the order depicted in FIG. 3. Further, the method 300 may include additional or fewer operations than those depicted in FIG. 3 to process the semiconductor substrate.

At block 310, the method 300 may include receiving an edge portion of the semiconductor substrate at a region between a first electrodes and a second electrode. In some embodiments, the region may include one or more ledge features each configured to prevent at least plasma from diffusing out of the region. One or more of confinement ledges 252 and 253 illustrated in FIGS. 2H and 2I may be examples of the one or more ledge features. In some embodiments, the substrate may be positioned into the region between first and second electrodes using an aligner that is configured to hold (e.g., via vacuum chuck or electrostatic chuck) and move the substrate (e.g., via X-Y-Z actuation) toward the region. The region may be a process volume where portions of the substrate (e.g., the edge) may be processed using EBR (e.g., etched). The first and second electrodes may be part of respective assemblies, each of which may be configured to actuate (e.g., in X-Y-Z directions). For example, the upper and/or the lower assemblies may increase the gap between them (moving in opposing Z directions), receive the substrate, and reduce the gap such that a small gap is created between the substrate and a surface of the upper subassembly and another small gap is created between the substrate and a surface of the lower subassembly. In some cases, the small gap may have a distance of about 100 microns or less, e.g., 3 mils or less. In some cases, the other small gap between the substrate and the surface of the lower subassembly may be even smaller, e.g., under about 10 microns.

In some implementations, inert aerostatic bearing gas (e.g., argon, helium, nitrogen, oxygen, air) may be introduced into this small gap (e.g., through an opening at the upper subassembly) for precise gap control, assist in removing etched matter, and/or provide a low-friction bearing for spinning the substrate.

At block 320, the method 300 may include receiving a process gas and an inert gas from one or more inlets. In some embodiments, the process gas may include an etchant gas received via a first inlet of the one or more inlets, and the inert gas may include a carrier gas received via a second inlet of the one or more inlets. Examples of the process gas may be oxygen-based, fluorine-based, hydrogen-based, or chlorine-based chemistries. Examples of the carrier gas may include argon, neon, or helium. In some embodiments, the process gas, the inert gas, or a mixture thereof may have a total pressure of about 200 Torr, or more in some cases.

At block 330, the method 300 may include, using the first and second electrodes and the process gas, generating a point plasma confined in the region between the first and second electrodes by the one or more ledge features, the point plasma having a pressure of at least 200 Torr. In some embodiments, the plasma pressure may be atmospheric pressure. In some embodiments, the plasma pressure may be a fraction of atmospheric, e.g., at least 200 Torr or at least 300 Torr, or between about 300 Torr and about 760 Torr.

In some embodiments, the plasma may be generated from a capacitively coupled plasma (CCP) source using direct plasma generation, as discussed with respect to FIG. 2E. For example, RF power may be applied to the process gas, which may be a reactive species (e.g., etchant gas such as oxygen), using the first electrode and the second electrode to create plasma radicals that serve as an etchant at the region. The radicals are generated directly on the substrate edge. Thus, there is no transportation of the radicals involved, which may reduce loss of radicals (e.g., via recombination) and thereby improve etch rate and etch profile during etching (block 330).

At block 340, the method 300 may include etching the edge portion the semiconductor substrate using an etchant produced on the edge portion by the point plasma while the semiconductor substrate is rotating between and relative to the first and second electrodes. In some embodiments, an example rate of the etching may be about or at least about 1 mm per minute, which is advantageously higher than in traditional EBR. In some embodiments, the example rate of the etching may be less than 1 mm per minute. Such etch rates may correspond to instantaneous etch rate in the plasma zone, or time-averaged effective etch rate of the entire perimeter of the wafer. The etchant may be selected based on the material to be etched. For example, with an oxygen-based etchant, carbon-based film may be etched from the substrate edge. In some embodiments, the substrate may be rotated by the aligner or the chuck holding the substrate. The rate of rotation may vary, e.g., between 60-120 rotations per minute. An example rate of rotation may be 100 rotations per minute.

In some implementations, a separate inert purge gas (e.g., hydrogen, argon, helium, nitrogen, oxygen, air) may be provided to prevent etched matter from diffusing toward the center of the substrate, although in some implementations, at least one confinement ledge may also provide solid blockage to prevent etched matter from reaching other portions of the substrate away from the edge. Confinement ledges 252 and 253 illustrated in FIGS. 2H and 2I may be examples of the at least one confinement ledge.

In alternate embodiments, an apparatus configured to process a semiconductor substrate may include a controller coupled to first and second electrodes and a power source, the controller configured to apply power from the power source to the first and second electrodes to cause generation of plasma in the region using the first and second electrodes based at least on a process gas received via the first inlet, the process gas delivered to the region with a carrier gas from the second inlet, the plasma at least partially confined in the region by the one or more confinement ledges and having a pressure of at least 200 Torr, and etch at least the portion of the semiconductor substrate using the generated plasma while the semiconductor substrate is rotating, wherein a rate of the etching may be about 1 millimeter (mm) per minute, or the etch rate may be less than 1 mm per minute.

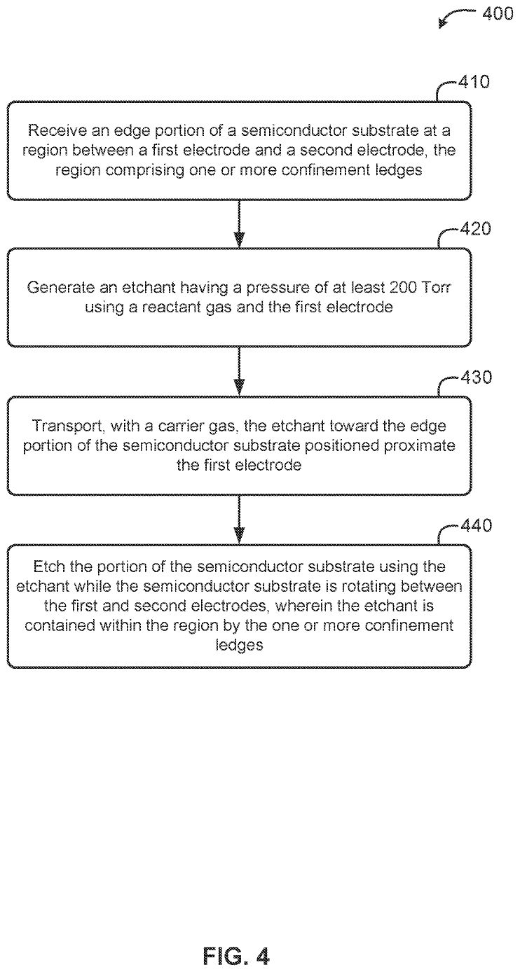

FIG. 4 is a flow diagram illustrating a method 400 of processing a semiconductor substrate, according to some embodiments. The substrate may have a frontside, the frontside having electronic device features fabricated thereon. One or more blocks of the method 400 may be performed by or caused by an apparatus or system controlled by a computing device. Such a system may include various hardware components, such as one or more electrodes, RF power supply, and/or actuator (e.g., stage, aligner) as described above. Structure for performing the functionality illustrated in one or more of the blocks shown in FIG. 4 may include hardware and/or software components of such apparatus or system, or computing device, such as, for example, a controller or a computer-readable apparatus including a storage medium storing computer-readable and/or computer-executable instructions that are configured to, when executed by a processor apparatus, cause the processor apparatus to perform the operations. Example components of the apparatus or system are discussed with respect to FIG. 5 below.

It should also be noted that the operations of the method 400 may be performed in any suitable order, not necessarily the order depicted in FIG. 4. Further, the method 400 may include additional or fewer operations than those depicted in FIG. 4 to process the semiconductor substrate.

At block 410, the method 400 may include receiving an edge portion of the semiconductor substrate at a region between a first electrode and a second electrode. In some embodiments, the region may include one or more confinement ledges (e.g., 252 and/or 253). This operation may be implemented similarly to block 310 and will not be repeated for brevity. In some implementations, inert aerostatic bearing gas (e.g., argon, helium, nitrogen, oxygen, air) may be introduced into a small gap as discussed above.

At block 420, the method 400 may include generating an etchant having a pressure of at least 200 Torr using a reactant gas and the first electrode. In some embodiments, an inert gas may also be introduced with process gas (e.g., the reactant gas), and the process gas and the inert gas may have a total pressure of at least 200 Torr. In some embodiments, the etchant may be plasma radicals generated from an inductively coupled plasma (ICP) source using indirect plasma generation, as discussed with respect to FIG. 2D. For example, RF power may be applied to a process gas, which may be a reactive species (e.g., etchant gas such as oxygen), using the first electrode. An example of the first electrode may be the upper electrode of the upper electrode subassembly 202. Other electrodes such as the second electrodes may not be involved in the generation of the etchant in indirect plasma generation. RF power may not be applied to the electrodes other than the first electrode. In some embodiments, the plasma pressure may be about atmospheric pressure (about 760 Torr) or a fraction of atmospheric, e.g., at least 200 Torr or at least 300 Torr.

At block 430, the method 400 may include transporting, with a carrier gas, the etchant toward the edge portion of the semiconductor substrate positioned proximate the first electrode. In some cases, the carrier gas may be an inert carrier gas (e.g., argon, neon, helium) that may be used to carry plasma radicals of the etchant out of the plasma source, e.g., via a nozzle or tip. The edge portion of the semiconductor substrate may be positioned directly underneath such a nozzle or tip such that the edge portion is exposed to the transported plasma radicals.

At block 440, the method 400 may include etching the portion of the semiconductor substrate using the etchant while the semiconductor substrate is rotating between the first and second electrodes. In some embodiments, the etchant may be contained within the region by the one or more confinement ledges. In some embodiments, an example rate of the etching may be about or at least about 1 mm per minute, which is advantageously higher than in traditional EBR. In some embodiments, the example rate of the etching may be less than 1 mm per minute. The etchant may be selected based on the material to be etched. For example, with an oxygen-based etchant, carbon-based film may be etched from the substrate edge. In some embodiments, the substrate may be rotated by the aligner or the chuck holding the substrate. The rate of rotation may vary, e.g., between 60-120 rotations per minute (RPM). An example rate of rotation may be 100 rotations per minute. In some implementations, the rate of rotation may be as low as 10 RPM or up to 300 RPM.

In some implementations, a separate inert purge gas (e.g., hydrogen, argon, helium, nitrogen, oxygen, air) may be provided to prevent etched matter from diffusing toward the center of the substrate, although in some implementations, at least one confinement ledge may also provide solid blockage to prevent etched matter from reaching other portions of the substrate away from the edge. Confinement ledges 252 and 253 illustrated in FIGS. 2H and 2I may be examples of the at least one confinement ledge.

### Apparatus—Computational and Controller Embodiments

FIG. 5 illustrates a simplified block diagram of an APPJ-based material removal system or apparatus 500 as described herein, which may include at least one subassembly 510, at least one actuator 520 (e.g., chuck, aligner), and at least one controller apparatus 530 coupled to the subassembly 510 and/or the actuator 520. The subassembly 510 may include, in some embodiments, one or more sub-assemblies, examples of which include an upper subassembly and a lower subassembly having respective one or more electrodes 512 associated therewith (e.g., upper electrode(s) and lower electrode(s)). Hence, the at least one controller apparatus 530 may be configured to be coupled to the one or more electrodes 512. The at least one controller apparatus 530 may also be configured to be coupled to an external RF power source 521. The controller(s) 530 may use an internal RF power source 519 and/or the external RF power source 521 to cause power to be provided to at least components of the subassembly 510 and/or the actuator 520. The subassembly 510 may further include, in some embodiments, one or more gas inlets (or inlet lines) 514. Examples of gas inlets 514 may include a first gas inlet to provide a process gas (and/or a curtain gas) and/or a second gas inlet to provide a purge gas. The inlets 514 may be configured to deliver gas and/or plasma from a source to an outlet of the nozzle(s) 516. An axis of the nozzle(s) 516 may be at an angle relative to a plane parallel to the substrate, the angle being adjustable between orthogonal to non-orthogonal (angled). In some embodiments, the actuator 520 may include a chuck (e.g., a vacuum chuck, electrostatic clamp) and/or an aligner configured to hold, move (e.g., along X-Y-Z-R-θ), and/or rotate the substrate 502 while the substrate 502 is positioned proximate a portion of the subassembly 510 (e.g., between upper and lower electrode assemblies with a small gap above the substrate 502 for purge gas or aerostatic bearing gas to flow). In some embodiments, the actuator 520 may include a stage (e.g., X-Y-Z) configured to actuate at least portions of the subassembly 510. For example, the aligner may hold and move the substrate 502 in X-Y-Z into a space between upper or lower assemblies movable vertically to receive the substrate 502, according to implementations described herein.

In some embodiments, the subassembly 510 may include at least one nozzle 516 that is at least partially housed by the subassembly 510 or by a nozzle housing which may in turn be at least partially housed in the subassembly 510. The nozzle 516 may be configured to direct a plasma jet into a process volume where a portion of the substrate 502 is positioned, and thereby etch and remove materials, e.g., on the edge of the substrate 502. The actuator 520 may be configured to adjustably position the substrate 502 with respect to the nozzle(s) 516 during etching, and the controller(s) 530 may be configured to control an internal RF power source 519 and/or an external RF power source 521 to provide power, e.g., to a plasma source 518, to generate plasma radicals that etch the substrate edge. The plasma source 518 may be a direct plasma source (e.g., RF power may be applied to the upper electrode and the lower electrode) or an indirect plasma source (e.g., RF power may be applied to the upper electrode).

The apparatus 500 may be configured to implement the foregoing aforementioned methods 300 and 400 using one or more of the foregoing aforementioned components 510-530. In some embodiments, operation of the apparatus 500 may include generating and/or transporting plasma radicals from the plasma source 518 at about atmospheric pressure or a fraction thereof (e.g., at least at about 200-300 Torr), which may cause enhanced etching of a portion or edge of the substrate 502 in conjunction with purge gas and/or aerostatic bearing gas. The apparatus 500 may advantageously enable an etching rate of, for example, about or at least about 1 mm per minute.

In various configurations, the controller(s) 530 may be further configured to adjust one or more process conditions during an operation of the apparatus 500. The process conditions may include: a rotation rate of the substrate 502 using the actuator 520, a position and/or an angle associated with the nozzle(s) 516, RF power of the RF power source 519, a plasma power associated with the plasma jet of the nozzle(s) 516, an RF frequency associated with the plasma jet of the nozzle(s) 516, a residence time of the plasma jet at a location on the substrate, a gas flow rate, a gas composition, a gas pressure, or any combination thereof. In some cases, the controller(s) 530 may be configured to adjust plasma power during a single rotation of the substrate 502. In some cases, the controller(s) 530 may be configured to adjust plasma power (e.g., high/low or on/off) repeatedly over numerous rotations of the substrate 502.

In some implementations, the actuator 520 may be configured to rotate the substrate 502 during EBR/etching of the substrate edge. The actuator 520 may also be configured to cause the substrate 502 to translate (e.g., x- and/or y-axis) along a plane parallel to the substrate, or along a plane orthogonal to the plane parallel to the substrate (e.g., z-axis), or cause the substrate to move radially relative to the substrate. Depending on the application, the rotation speed of the substrate may be 60-120 rotations per minute. In one example, the rate of rotation may be about 100 rotations per minute. The actuator 520 may also be configured to provide rasterized deposition of the material. The actuator 520 may also be configured to maintain a small gap between the substrate and surfaces of the subassembly 510 during etching, and wherein the gap may be between about 0 and 100 microns.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

In some implementations, a “controller” (e.g., 190) is part of a system containing a various types of sensors as described herein. Such systems include a fabrication tool with a camera sensor. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The controller may be implemented with or coupled to analysis logic as described above. A controller may be implemented as logic such as electronics having one or more integrated circuits, memory devices, and/or software that receive instructions, issue instructions, control operation, and/or enable sensing operations.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a wafer.

A controller may be configured to control or cause control of various components or subparts of the system or systems. The controller, depending on the processing requirements and/or the type of system, may be programmed to control any of the processes that may be used by a fabrication tool during a fabrication operation, including adjusting or maintaining the delivery of processing gases, temperature settings (e.g., heating and/or cooling) including substrate temperature and chamber wall temperature, pressure settings including vacuum settings, plasma settings, RF matching circuit settings, and substrate positional and operation settings, including substrate transfers into and out of a fabrication tool and/or load lock. Process gas parameters include the process gas composition, flow rate, temperature, and/or pressure. Of particular relevance to the disclosed embodiments, controller parameters may relate to plasma generator power, pulse rate, and/or RF frequency.

Process parameters under the control of a controller may be provided in the form of a recipe and may be entered utilizing a user interface. Signals for monitoring the process may be provided by analog and/or digital input connections of the system controller. The signals for controlling the process are output on the analog and digital output connections of the deposition apparatus.

In one example, the instructions for bringing about ignition or maintenance of a plasma are provided in the form of a process recipe. Relevant process recipes may be sequentially arranged, so that at least some instructions for the process can be executed concurrently. In some implementations, instructions for setting one or more plasma parameters may be included in a recipe preceding a plasma ignition process. For example, a first recipe may include instructions for a first time delay, instructions for setting a flow rate of an inert gas (e.g., helium) and/or a reactant gas, and instructions for setting a plasma generator to a first power set point. A second, subsequent recipe may include instructions for a second time delay and instructions for enabling the plasma generator to supply power under a defined set of parameters. A third recipe may include instructions for a third time delay and instructions for disabling the plasma generator. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example. As explained, plasma may be pulsed.

In some embodiments, a controller is configured to control and/or manage the operations of a RF signal generator. In certain implementations, a controller is configured to determine upper and/or lower thresholds for RF signal power to be delivered to a fabrication tool, determining actual (such as real-time) levels of RF signal power delivered to integrated circuit fabrication chamber, RF signal power activation/deactivation times, RF signal modulation duration (for, e.g., high/low or on/off states), duty cycle, operating frequency, and so forth.

As further examples, a controller may be configured to control the timing of various operations, mixing of gases, the pressure in a fabrication tool, the temperature in a fabrication tool, the temperature of a substrate or pedestal, the position of a pedestal, chuck and/or susceptor, and a number of cycles performed on one or more substrates.

A controller may comprise one or more programs or routines for controlling designed subsystems associated with a fabrication tool. Examples of such programs or routines include a substrate positioning program, a process gas control program, a pressure control program, a heater control program, and a plasma control program. A substrate positioning program may include program code for process tool components that are used to load the substrate onto a pedestal and to control the spacing between the substrate and other parts of a fabrication tool. A positioning program may include instructions for moving substrates in and out of the reaction chamber to deposit films on substrates and clean the chamber.

A process gas control program may include code for controlling gas composition and flow rates and for flowing gas into one or more process stations prior to deposition to bring about stabilization of the pressure in the process station. In some implementations, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing numbers of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some implementations, there may be a user interface associated with a controller. The user interface may include a display screen, graphical software displays of the apparatus and/or process conditions, and user input devices such as pointing devices, keyboards, touch screens, microphones, etc.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

The system software may be organized in many different ways that may have different architectures. For example, various chamber component subroutines or control objects may be written to control operation of the chamber components necessary to carry out the deposition processes (and other processes, in some cases) in accordance with the disclosed embodiments.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of processing a semiconductor substrate, the method comprising:
receiving at least an edge portion of the semiconductor substrate at a region between a first electrode and a second electrode, the region comprising one or more ledge features each configured to prevent plasma from diffusing out of the region;
receiving a process gas and an inert gas from one or more inlets;
using the first and second electrodes and the process gas, generating a point plasma confined in the region between the first and second electrodes by the one or more ledge features, the point plasma having a pressure of at least 200 Torr; and
etching the edge portion of the semiconductor substrate using an etchant produced on the edge portion by the point plasma while the semiconductor substrate is rotating between and relative to the first and second electrodes.

2. The method of claim 1, wherein the process gas comprises an etchant gas received via a first inlet, and the inert gas comprises a carrier gas received via a second inlet.

3. The method of claim 1, wherein the pressure of the plasma is between about 300 Torr and about 760 Torr.

4. The method of claim 1, wherein generating plasma in the region between the first and second electrodes comprises applying radio frequency (RF) power to both the first electrode and the second electrode to produce the etchant directly on the edge portion of the of the semiconductor substrate.

5. The method of claim 1, wherein a rate of rotation of the semiconductor substrate is at least 10 rotations per minute.

6. The method of claim 1, wherein a rate of rotation of the semiconductor substrate is up to 300 rotations per minute.

7. The method of claim 1, wherein the process gas comprises an etchant gas, and the point plasma confined in the region is generated based on the etchant gas.

8. The method of claim 7, wherein the etchant gas comprises oxygen-based, fluorine-based, hydrogen-based, or chlorine-based chemistries.

9. The method of claim 1, wherein:
the receiving at least the edge portion of the semiconductor substrate comprises positioning a portion of the semiconductor substrate proximate to a first surface of a first hardware component associated with the first electrode and proximate to a second surface of a second hardware component associated with the second electrode; and
a gap between the first surface and the semiconductor substrate comprises a distance of 100 microns or less.

10. The method of claim 9, further comprising emitting a purge gas through the gap between the first surface and the semiconductor substrate, wherein the purge gas comprises an inert gas, a process gas, or a combination thereof.

11. The method of claim 9, further comprising emitting an aerostatic bearing gas through the gap between the first surface and the semiconductor substrate, wherein the aerostatic bearing gas comprises argon, helium, nitrogen, oxygen, or a combination thereof.

12. The method of claim 1, further comprising selecting a radial position at which the edge portion of the semiconductor substrate is etched, wherein the etching comprises removing a material deposited at the radial position.

13. An apparatus configured to process a semiconductor substrate, the apparatus comprising:
a first electrode;
a second electrode disposed opposite to the first electrode to form a region sized to receive at least a portion of the semiconductor substrate between the first electrode and the second electrode, wherein the first and second electrodes are configured to couple to a power source;
one or more confinement ledges proximate the region and configured to confine gas and plasma;
a first gas inlet;
a second gas inlet; and
a controller configured to couple to the first and second electrodes and the power source, the controller further configured to:
when coupled to the first and second electrodes and the power source, apply power from the power source to the first and second electrodes to cause generation of plasma in the region using the first and second electrodes based at least on a process gas received via the first gas inlet, the process gas delivered to the region with a carrier gas from the second gas inlet, the plasma at least partially confined in the region by the one or more confinement ledges and having a pressure of at least 200 Torr, and etch at least the portion of the semiconductor substrate using the generated plasma while the semiconductor substrate is rotating.

14. The apparatus of claim 13, wherein the pressure of the plasma is between about 300 Torr and about 760 Torr.

15. The apparatus of claim 13, wherein the process gas comprises oxygen-based, fluorine-based, hydrogen-based, or chlorine-based chemistries.

16. The apparatus of claim 13, further comprising:
an upper subassembly and a lower subassembly, the upper subassembly comprising the first electrode and a first surface, the lower subassembly comprising the second electrode and a second surface; and
an opening to provide an inert gas to a gap between the semiconductor substrate and the first surface;
wherein:
the first surface is configured to provide aerostatic bearing for the semiconductor substrate using the inert gas; and
the apparatus is configured to receive the at least the portion of the semiconductor substrate between the upper subassembly and the lower subassembly.

17. The apparatus of claim 16, further comprising at least one confinement ledge configured to prevent at least a portion of the generated plasma from flowing into the gap between the semiconductor substrate and the first surface.

18. The apparatus of claim 16, further comprising a dielectric barrier associated with the upper subassembly and a dielectric barrier associated with the lower subassembly.

19. A method of processing a semiconductor substrate, the method comprising:
receiving an edge portion of the semiconductor substrate at a region between a first electrode and a second electrode, the region comprising one or more confinement ledges;
generating an etchant having a pressure of at least 200 Torr using a reactant gas and the first electrode;
transporting, with a carrier gas, the etchant toward the edge portion of the semiconductor substrate positioned proximate the first electrode; and
etching the edge portion of the semiconductor substrate using the etchant while the semiconductor substrate is rotating between the first and second electrodes, wherein the etchant is contained within the region by the one or more confinement ledges.

20. The method of claim 19, wherein the reactant gas comprises oxygen-based, fluorine-based, hydrogen-based, or chlorine-based chemistries.
